(19) United States
(12) Patent Application Publication
(10) Pub. No.: US 2015/0103585 A1
(43) Pub. Date: Apr. 16, 2015

(54) High stability static random access memory cell

(71) Applicant: UNITED MICROELECTRONICS CORP., Hsin-Chu City (TW)

(72) Inventors: Young-Ran Chuang, Tainan City (TW); Chao-Hsien Wu, Hsinchu City (TW); Ming-Shing Chen, Tainan City (TW)

(73) Assignee: UNITED MICROELECTRONICS CORP., Hsin-Chu City (TW)

(21) Appl. No.: 14/051,471

(22) Filed: Oct. 11, 2013

(51) Int. Cl. G11C 11/412

(52) U.S. Cl. CPC G11C 11/412
USPC 365/156

(57) ABSTRACT

A Static Random Access Memory (SRAM) cell is a latch circuit formed with two inverters each formed with a PMOS transistor and an NMOS transistor. The latch circuit is coupled to a capacitor through a switch. When the switch is switched on, the stability of data stored in the SRAM cell will be enhanced. When the switch is switched off, data can be written to the SRAM cell quickly.

### BACKGROUND OF THE INVENTION

1. Field of the Invention

The present invention relates to a static random access memory cell, and more particularly, a high stability static random access memory cell.

2. Description of the Prior Art

Static random access memory (SRAM) has been widely used in applications such as CPU cache and buffer cache. This is due to the reasons that a static random access memory has a high access speed, low power consumption, simple control circuit, low power dissipation and other features. In prior art, the static random access memory cell has a core circuit composed of two CMOS inverter circuits configured to form a latch circuit. When a bit data is entered into a latch, the latch shall store the bit data. Please refer to FIG. 1. FIG. 1 is an illustration a static random access memory cell 100 with six transistors of the prior art. When a bit 1 is stored in the static random access memory cell 100, a storage node NA shall latch to logic 1 and a storage node NB shall latch to logic 0. When a bit 0 is stored in the static random access memory cell 100, a storage node NA shall latch to latch 0 and a storage node NB shall latch to logic 1. The voltage stored in the storage node NA and the storage node NB can be written or read in bit line BL and bit line bar BLB respectively.

Please refer to FIG. 2. FIG. 2 is static noise margin (SNM) corresponding to the static random access memory cell 100. The SNM is taken from the voltage curve of the two CMOS inverter forming a butterfly curve. The SNM is defined by the side length of the largest possible square taken from the butterfly curve. A larger SNM means a better resistance of the static random access memory cell 100 against DC noise. Since a read and a write operation of the static random access memory cell 100 is similar to each other, the risk of mistaking the read operation as the write operation is lowered when the static random access memory cell 100 has high SNM. The illustrated SNM in FIG. 2 only shows a side length of the square to be at 0.2 volts.

Please refer to FIG. 3. FIG. 3 is a write margin WRM corresponding to the static random access memory cell 100. The write margin WRM is used to observe a transition voltage. As shown in FIG. 3, a solid line shall represent voltage V_{NA} of the storage node NA of static random access memory cell 100 and a dotted line shall represent voltage V_{NB} of the storage node NB of static random access memory cell 100. A decreasing voltage V_{BL} is supplied to the bit line BL. An output high voltage VOH of 1.2 volts and an output low voltage VOL of 0.2 volts are defined for the static random access memory cell 100. The output high voltage VOH shall represent logic 1 and VOL shall represent logic 0. The write margin WRM is defined as a V_{BL} voltage where V_{NA} is the average of the output high voltage VOH and the output low voltage VOL. As shown in FIG. 3, the static random access memory cell 100 reaches the write margin WRM when V_{BL} voltage is at 0.45 volts. When the write margin WRM is at a lower V_{BL} value, it can be said that the write margin WRM is lower. A low write margin WRM would mean more stable data retention for a static random access memory cell.

Please refer to FIG. 4. FIG. 4 is a curve for a High Temperature Operating Life (HTOL) of the static random access memory cell 100, where a minimum value of operating voltage (Vcc_min) is observed. A lower Vcc_min value shall mean a more stable static random access memory cell. The static random access memory cell 100 is placed in a high temperature environment to test for its rapid aging and reliability and is shown to have a rising value for Vcc_min as the operating temperature increases.

Although the static random access memory cell 100 can retain data, it entirely relies on the parasitic capacitance on storage nodes NA and NB. The stability of the static random access memory cell 100 is decreased when exposed to high temperature environment, high accessing speed and exposure to α-particle. Therefore, the static random access memory cell 100 is deemed to be prone to error. The embodiment of the present invention shall improve the stability and control system of the static random access memory cell 100 of the prior art.

### SUMMARY OF THE INVENTION

An embodiment of the present invention discloses a static random access memory cell. The static random access memory cell comprises a first PMOS transistor; a first NMOS transistor having a gate coupled to a gate of the first PMOS transistor; a second PMOS transistor having a source coupled to a source of the first PMOS transistor; a second PMOS transistor having a second NMOS transistor having a gate coupled to a gate of the second PMOS transistor and a source coupled to a source of the first NMOS transistor; a third switch having a first terminal coupled to a drain of the first PMOS transistor, a drain of the first NMOS transistor and the gate of the second PMOS transistor; a fourth switch having a first terminal coupled to a drain of the second PMOS transistor, a drain of the second NMOS transistor and the gate of the first PMOS transistor; a first switch having a first terminal coupled to the drain of the first PMOS transistor; and a first capacitor having a first terminal coupled to a second terminal of the first switch.

Another embodiment of the present invention discloses a method of operation of a static random access memory cell. The static random access memory cell comprises a first inverter, a second inverter cross coupled with the first inverter, a first capacitor, and a first switch coupled between the first inverter and the first capacitor. The method of operation of the static random access memory cell comprises switching off the first switch when data is to be written to the static random access memory cell.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a static random access memory cell with six transistors according to the prior art.

FIG. 2 illustrates a static noise margin of the static random access memory cell in FIG. 1.

FIG. 3 illustrates a write margin of the static random access memory cell in FIG. 1.

FIG. 4 illustrates a curve for a high temperature operating life observing a minimum operating voltage of the static random access memory cell in FIG. 1.

FIG. 5 illustrates a schematic diagram of a static random access memory cell according to the first embodiment of the present invention.

FIG. 6 illustrates a single side equivalent capacitance of the static random access memory cell shown in FIG. 5.

FIG. 7 illustrates a static noise margin of the static random access memory cell shown in FIG. 5.

FIG. 8 illustrates a write margin of the static random access memory cell shown in FIG. 5.

FIG. 9 illustrates a curve for a high temperature operating life observing a minimum operating voltage of the static random access memory cell shown in FIG. 5.

FIG. 10 illustrates control signals for a word line and a control line of the static random access memory cell shown in FIG. 5.

FIG. 11 illustrates a flowchart of a method of operation of the static random access memory cell shown in FIG. 5.

FIG. 12 illustrates a schematic diagram of a static random access memory cell according to the second embodiment of the present invention.

FIG. 13 illustrates a flowchart of a method of operation of the static random access memory cell shown in FIG. 12.

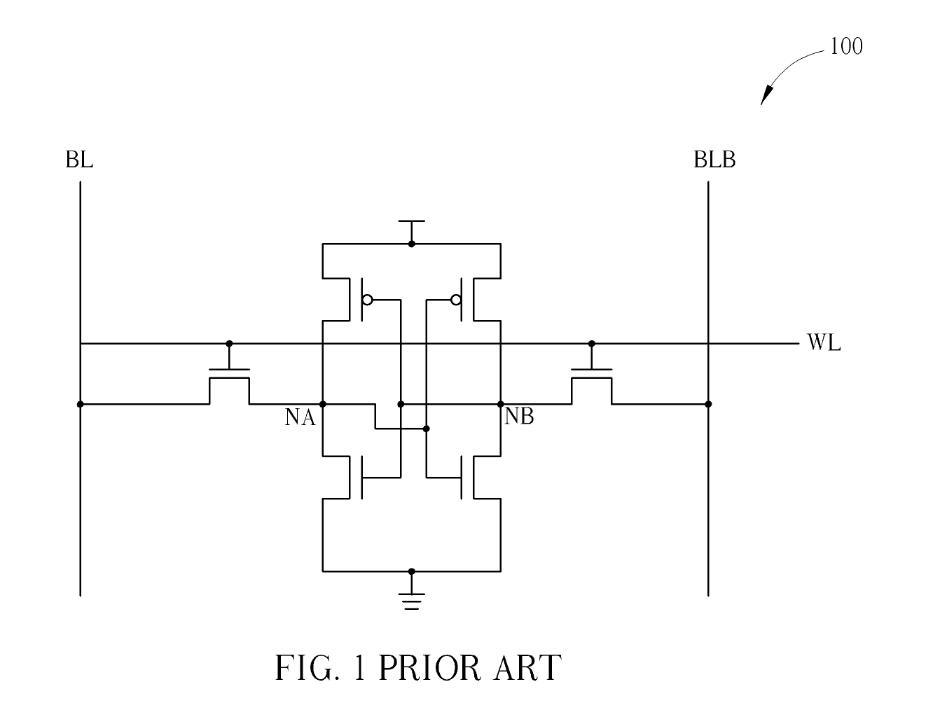

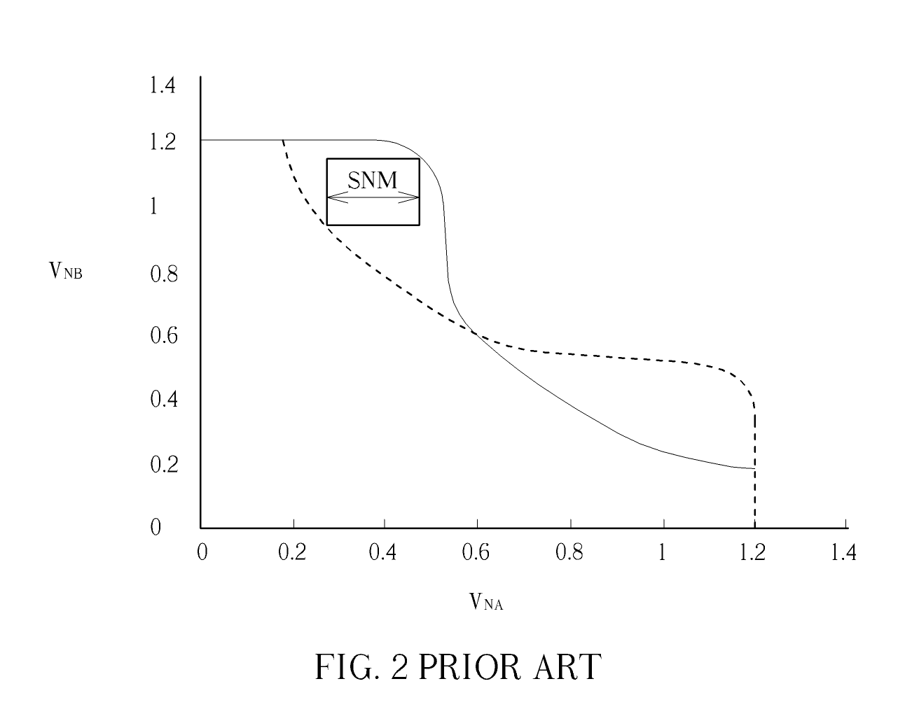

### DETAILED DESCRIPTION

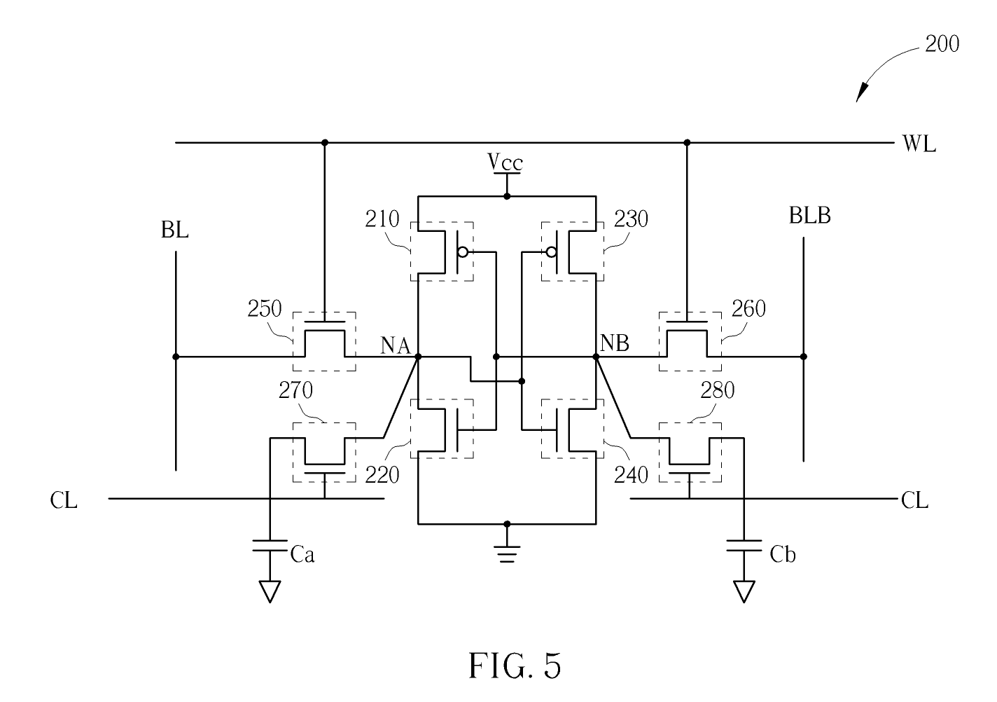

Please refer to FIG. 5. FIG. 5 is an illustration of a schematic diagram of a static random access memory cell 200 according to a first embodiment of the present invention. The static random access memory cell 200 comprises a first PMOS transistor 210, a first NMOS transistor 220, a second PMOS transistor 230, a second NMOS transistor 240, a third switch 250, a fourth switch 260, a first switch 270, a second switch 280, a first capacitor Ca, and a second capacitor Cb. The first NMOS transistor 220 has a gate coupled to a gate of the first PMOS transistor 210. The second PMOS transistor 230 has a source coupled to a source of the first PMOS transistor 210. The second NMOS transistor 240 has a gate coupled to a gate of the second PMOS transistor 230. The second NMOS transistor 240 has a source coupled to a source of the first NMOS transistor 220. The third switch 250 has a first terminal coupled to a drain of the first PMOS transistor 210, a drain of the first NMOS transistor 220 and the gate of the second PMOS transistor 230. The fourth switch 260 has a first terminal coupled to a drain of the second PMOS transistor 230, a drain of the second NMOS transistor 240 and the gate of the first PMOS transistor 210. The first PMOS transistor 210 and the first NMOS transistor 220 form a first inverter. The second PMOS transistor 230 and the second NMOS transistor 240 form a second inverter. The first and second inverters are cross coupled to one another.

The first switch 270 has a first terminal coupled to the drain of the first PMOS transistor 210. The first capacitor Ca has a first terminal coupled to a second terminal of the first switch 270. The second switch 280 has a first terminal coupled to the drain of the second PMOS transistor 230. The second capacitor Cb has a first terminal coupled to a second terminal of the second switch 280. The drain of the first PMOS 210 transistor is a first storage node NA. The drain of the second PMOS 230 is a second storage node NB. The first storage node NA is coupled to the first capacitor Ca through the first switch 270. The second storage node NB is coupled to the second capacitor Cb through the second switch 280. A second terminal of the third switch 250 is coupled to a bit line BL. A second terminal of the fourth switch 260 is coupled to a bit line bar BLB. The third switch 250 and the fourth switch 260 are controlled to switch on or off by a signal from a word line WL. The first switch 270 and the second switch 280 are controlled to switch on or off by a signal from a control line CL. The bit line BL and the bit line bar BLB shall provide the static random access memory cell 200 with the reading and writing data. A second terminal of the first capacitor and a second terminal maybe coupled to a ground, a voltage source or a metal layer, etc.

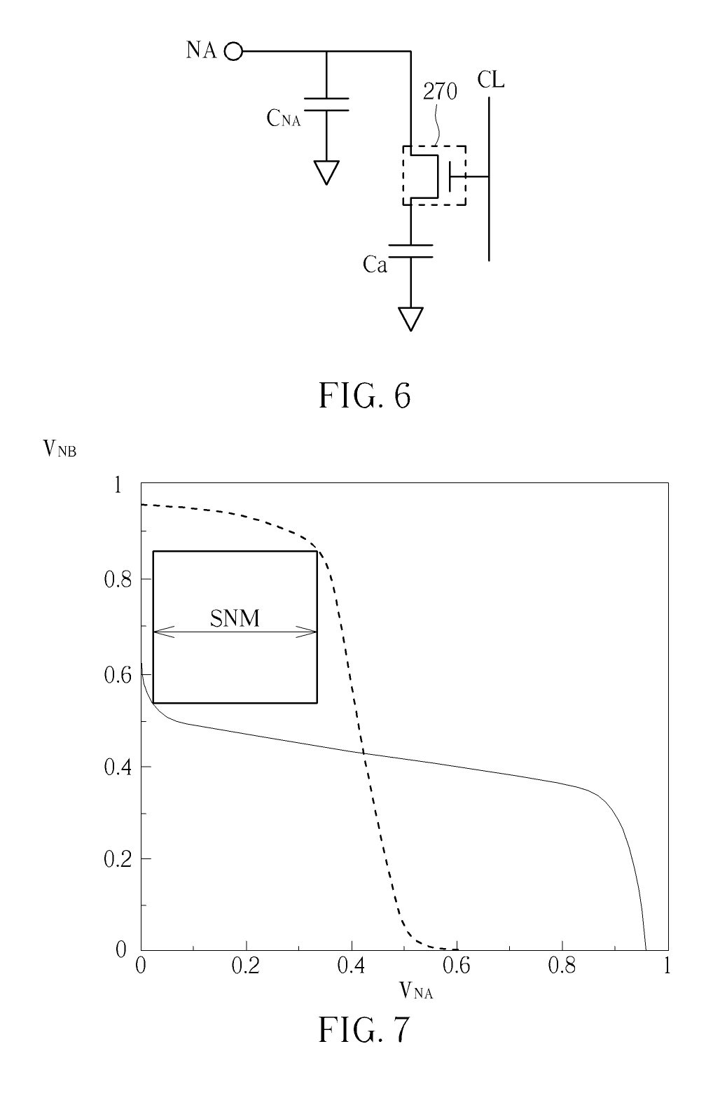

For the prior art, a data is retained in a static random access memory cell 100 relying on the parasitic capacitance on a storage node NA and a storage node NB. Please refer to FIG. 6. FIG. 6 illustrates a single side equivalent capacitance of shown in FIG. 5. The single side equivalent capacitance comprises a parasitic capacitance C_{NA} taken from storage node NA and the first capacitance Ca coupled in parallel. When the first switch 270 is switched on, an equivalent capacitance of the storage node NA of the static random access memory cell 200 shown in FIG. 6 is represented by the following equation:

C_{NA(NEW)}=C_{NA}+Ca (1)

Where C_{NA} indicates the parasitic capacitance of the storage node NA and Ca indicates the first capacitance. The equivalent capacitance of the storage node NA is the sum of the parasitic capacitance C_{NA} taken from storage node NA and the first capacitance Ca.

Please refer to FIG. 7. FIG. 7 illustrates a static noise margin of the static random access memory cell 200 shown in FIG. 5. When the first switch 270 and the second switch 280 are switched on, a side length of the square is 0.35 volts. When data is stored in the static random access memory cell 200 with the first switch 270 and the second switch 280 switched on, the static random access memory cell 200 will achieve a higher stability.

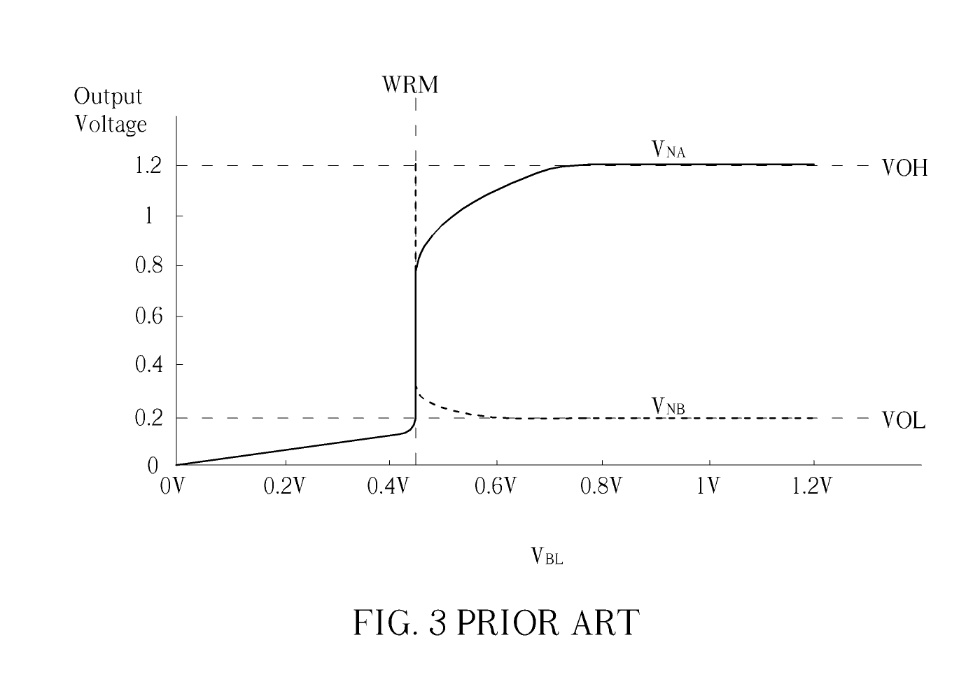

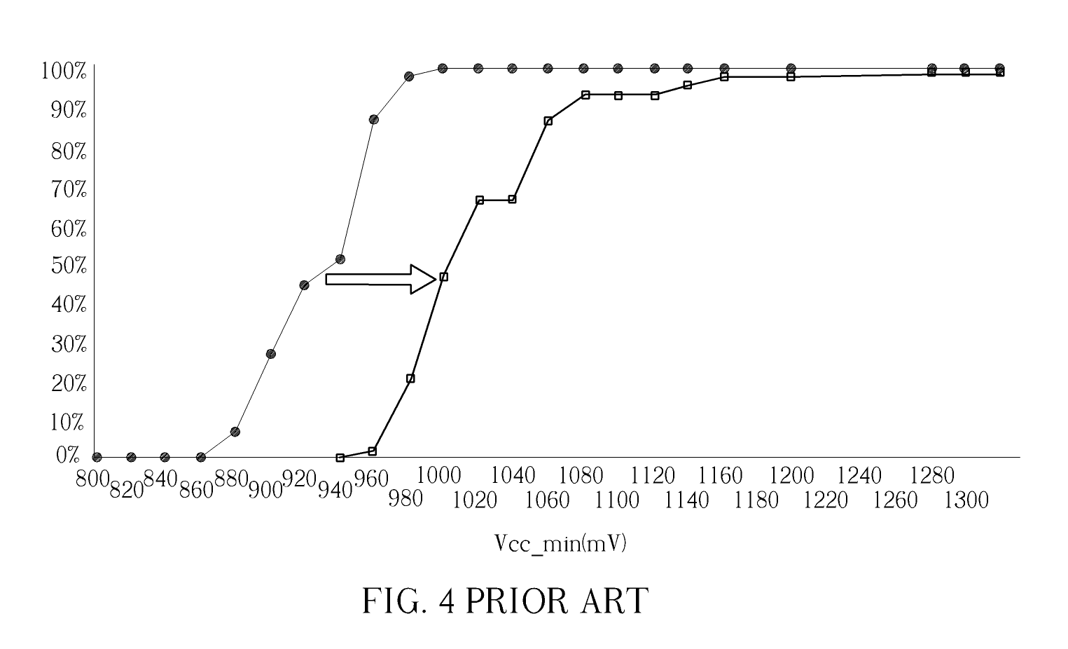

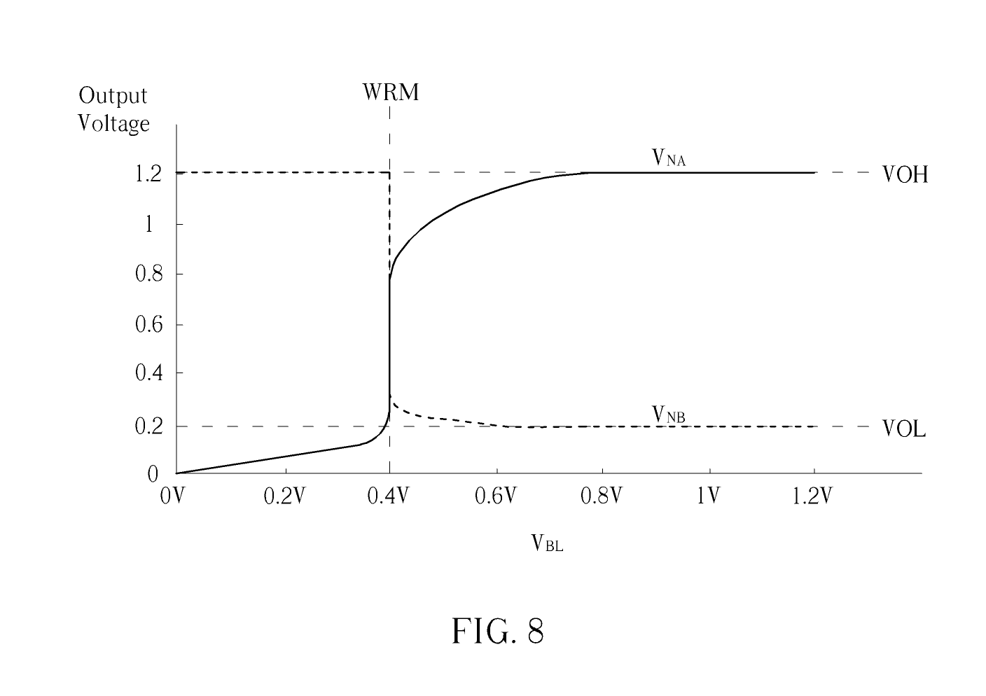

Please refer to FIG. 8. FIG. 8 illustrates a write margin WRM of the static random access memory cell 200 shown in FIG. 5. A solid line shall represent voltage V_{NA} of the storage node NA of static random access memory cell 200 and a dotted line shall represent voltage V_{NB} of the storage node NB of the static random access memory cell 200. A decreasing voltage V_{BL} is supplied to the bit line BL. As shown in FIG. 8, the write margin WRM is 0.4V which is lower than the write margin of 0.45V as shown in FIG. 3. According to the first embodiment of the present invention, the use of the first switch 270 and the second switch 280 by the static random access memory cell 200 has lowered the write margin WRM. Thereby, stability of data retention of the static random access memory cell 200 is improved.

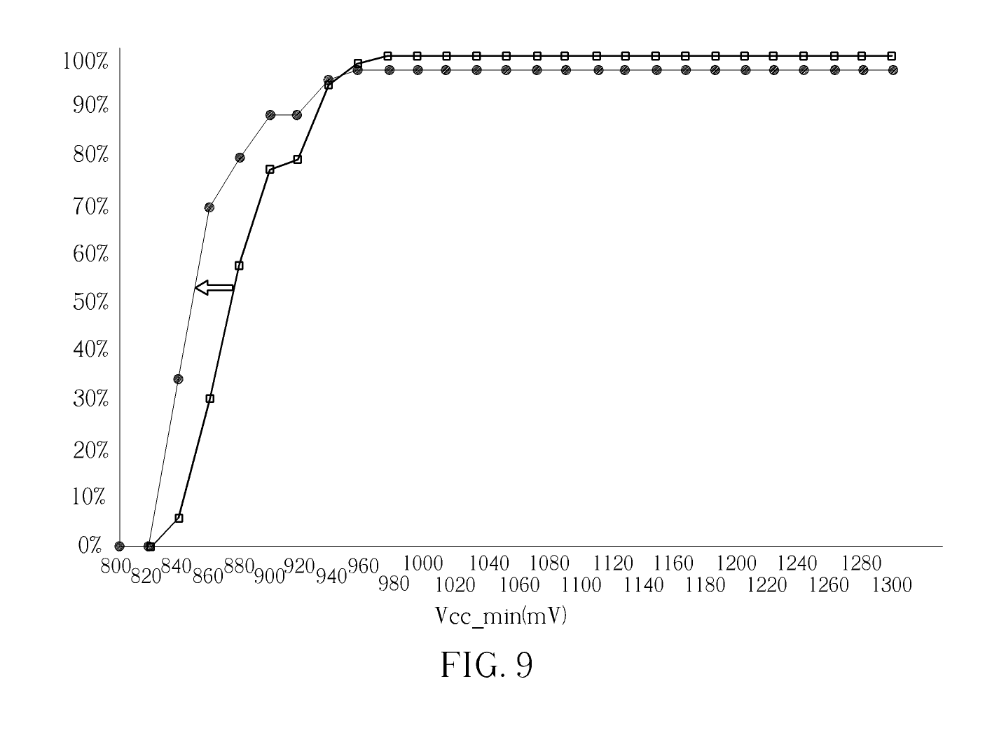

Please refer to FIG. 9. FIG. 9 is a curve for a high temperature operating life (HTOL) of the static random access memory cell 200 shown in FIG. 5, where a minimum value of operating voltage (Vcc_min) is observed. There is an observed improvement to the minimum value of operating voltage for the static random access memory cell 200 for the high temperature operating life. This is achieved with the use of the first capacitor Ca and the second capacitor Cb.

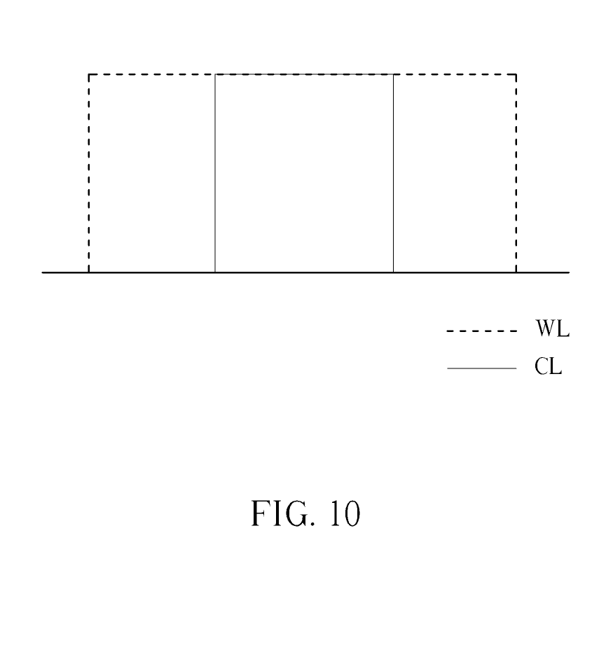

The use of the first switch 270 and the second switch 280 shows an improvement on the stability and better data retention for the static random access memory cell 200. Please refer to FIG. 10. FIG. 10 illustrates a control signal for the word line WL and the control line CL of the static random access memory cell 200 shown in FIG. 5. The static random access memory cell 200 may use the control signal from the control line CL to switch off the first switch 270 and the second switch 280. This will remove the coupling between the first storage node NA and the first capacitor Ca and the coupling between the second storage node NB and the second capacitor Cb. This will enhance the speed of writing data to the static random access memory cell 200. During mass production, the characteristics of the SRAM cells produced are different from each other. Researchers can make an SRAM module according to the experimental results to perform tuning on the SRAM cells. A programmable control circuit with a programming software can be used to produce the control signal for the control line CL. According to FIG. 10, the control signals for the word line WL and the control line CL are independent from each other. This will take into account, the difference in characteristics of SRAM cells and the tuning of the SRAM cells after production.

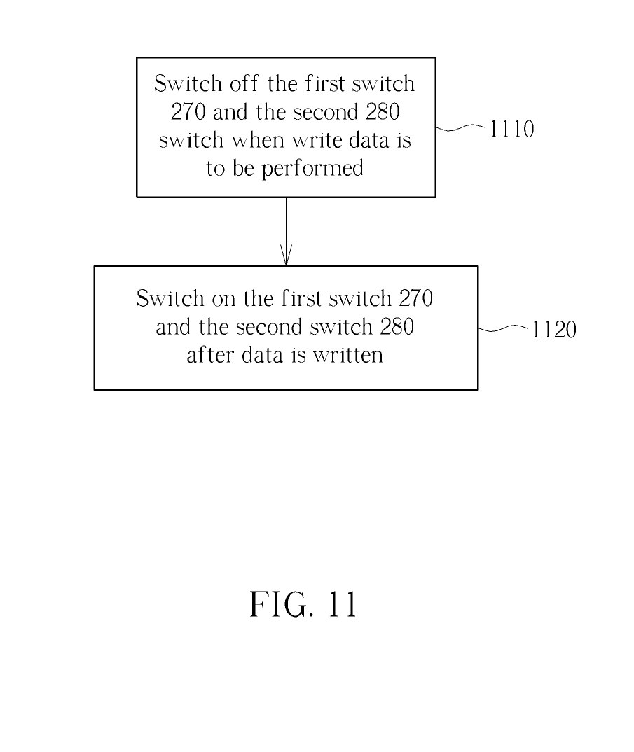

Please refer to FIG. 11. FIG. 11 illustrates a flowchart of a method of operation of the static random access memory cell 200 shown in FIG. 5. The method of operation is as follows but not limited to the following sequence:

Step 1110: Switch off the first switch 270 and the second switch 280 using the control signal of the control line CL when the bit line BL and bit line bar BLB are to perform write data on the static random access memory cell 200;

Step 1120: Switch on the first switch 270 and the second switch 280 after data is written to the static random access memory cell 200.

When the storage node NA and the storage node NB are not coupled to the first capacitor Ca and the second capacitor Cb, the writing speed is faster. Therefore, in step 1110, the first switch 270 and the second switch 280 are switched off during a write operation. And when the storage node NA and the storage node NB are coupled to the first capacitor Ca and the second capacitor Cb, the stability of the static random access memory cell 200 is higher. Therefore, in step 1120, the first switch 270 and the second switch 280 are switched on after the write operation. The control line CL coupled to the first switch 270 and the second switch 280 can be two separate signal lines so as to provide the first switch 270 and the second switch 280 the same or different switched on periods.

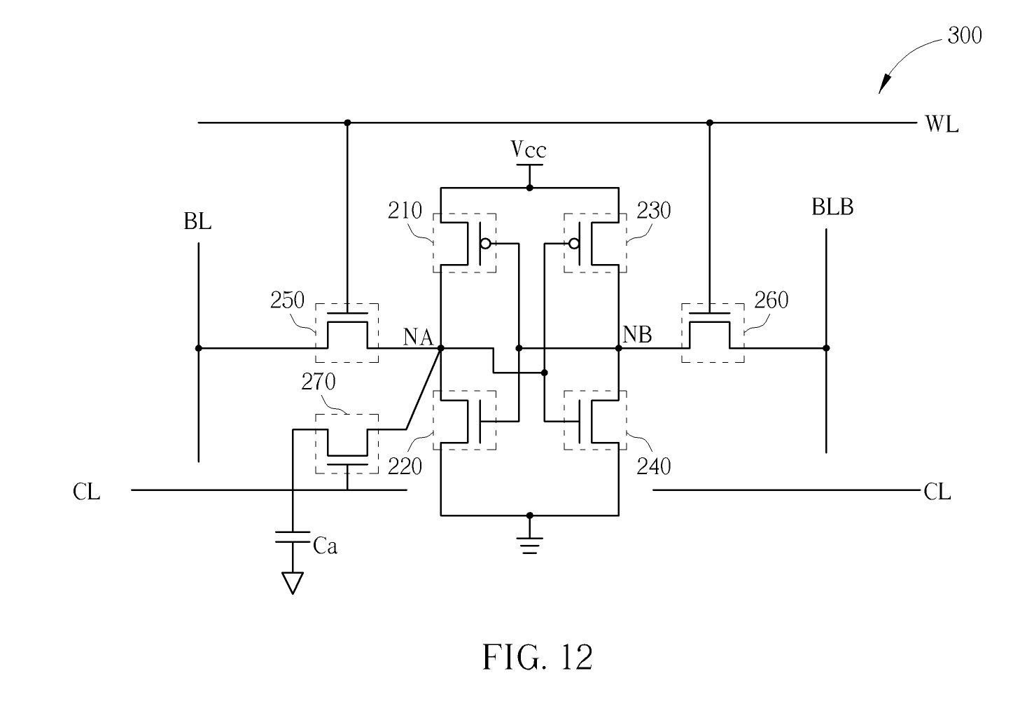

Please refer to FIG. 12. FIG. 12 illustrates a schematic diagram of a static random access memory cell 300 according to the second embodiment of the present invention. The static random access memory cell 300 comprises a first PMOS transistor 210, a first NMOS transistor 220, a second PMOS transistor 230, a second NMOS transistor 240, a third switch 250, a fourth switch 260, a first switch 270, and a first capacitor Ca. The first NMOS transistor 220 has a gate coupled to a gate of the first PMOS transistor 210. The second PMOS transistor 230 has a source coupled to a source of the first PMOS transistor 210. The second NMOS transistor 240 has a gate coupled to a gate of the second PMOS transistor 230. The second NMOS transistor 240 has a source coupled to a source of the first NMOS transistor 220. The third switch 250 has a first terminal coupled to a drain of the first PMOS transistor 210, a drain of the first NMOS transistor 220 and the gate of the second PMOS transistor 230. The fourth switch 260 has a first terminal coupled to a drain of the second PMOS transistor 230, a drain of the second NMOS transistor 240 and the gate of the first PMOS transistor 210. The first switch 270 has a first terminal coupled to the drain of the first PMOS transistor 210. The first capacitor Ca has a first terminal coupled to a second terminal of the first switch 270. The drain of the first PMOS 210 transistor is a first storage node NA. The drain of the second PMOS 230 is a second storage node NB. The first storage node NA is coupled to the first capacitor Ca through the first switch 270. Compared to the static random access memory cell 200, an area for a layout of the static random access memory cell 300 is reduced.

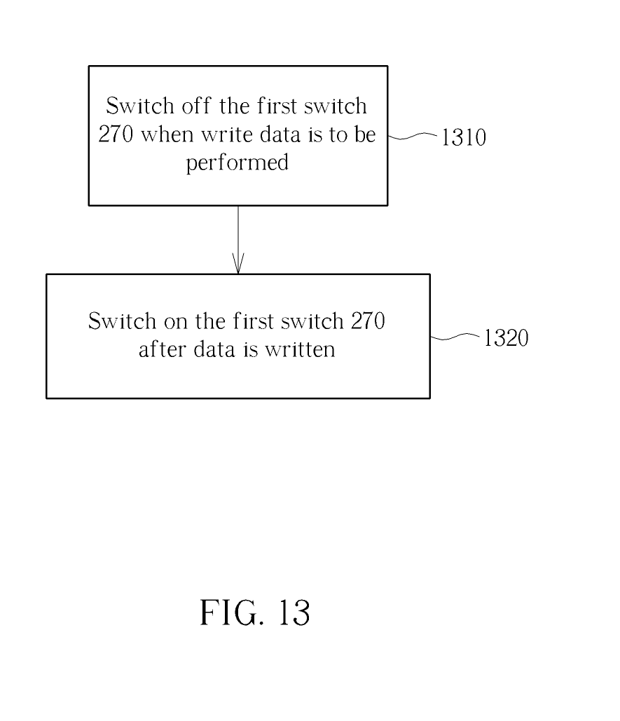

Please refer to FIG. 13. FIG. 13 illustrates a flowchart of a method of operation of the static random access memory cell shown in FIG. 12. The method of operation is as follows but not limited to the following sequence:

Step 1310: Switch off the first switch 270 using the control signal of the control line CL when the bit line BL and bit line bar BLB are to perform write data on the static random access memory cell 300;

Step 1320: Switch on the first switch 270 after data is written to the static random access memory cell 300.

With the high accessing speed of a static random access memory memory, it is gradually being used in a wide variety of application. The electronic equipments that use the static random access memory such as outdoor telecommunication equipments or observation equipment may be exposed to atmospheric interference. In recent years, cosmic ray a-particle is able to penetrate through packaging of the electronic equipments. This will cause a change in an electron hole on a storage node of a static random access memory cell. This phenomenon, which is called α-particle Accelerated Soft Error Rate, may cause the reversal of the data stored in the static random access memory cell. Such problem is seen on SRAM cells running a high speed operation. Therefore there is a need to resolve this problem. The present invention discloses a static random access cell where stored data is not easily reversed. This will help against a-particle Accelerated Soft Error Rate.

The present invention discloses a static random access memory cell has improved features comprising accessing speed, data storage stability, and tunability and controllability after production.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory cell, comprising:
a first PMOS transistor;
a first NMOS transistor having a gate coupled to a gate of the first PMOS transistor;
a second PMOS transistor having a source coupled to a source of the first PMOS transistor;
a second NMOS transistor having:
a gate coupled to a gate of the second PMOS transistor; and
a source coupled to a source of the first NMOS transistor;
a first switch having a first terminal coupled to the drain of the first PMOS transistor; and
a first capacitor having a first terminal coupled to a second terminal of the first switch.

2. The static random access memory cell of claim 1, further comprising:
a third switch having a first terminal coupled to a drain of the first PMOS transistor, a drain of the first NMOS transistor and the gate of the second PMOS transistor;
a fourth switch having a first terminal coupled to a drain of the second PMOS transistor, a drain of the second NMOS transistor and the gate of the first PMOS transistor.

3. The static random access memory cell of claim 2, wherein a control terminal of the third switch is coupled to a word line, a second terminal of the third switch is coupled to a bit line, a control terminal of the fourth switch is coupled to the word line, and a second terminal of the fourth switch is coupled to a bit line bar.

4. The static random access memory cell of claim 3, wherein the third switch is a third NMOS transistor, the control terminal of the third switch is a gate of the third NMOS transistor, the fourth switch is a fourth NMOS transistor, and the control terminal of the fourth switch is a gate of the fourth NMOS transistor.

5. The static random access memory cell of claim 1, wherein the first switch is an NMOS transistor or a PMOS transistor.

6. The static random access memory cell of claim 1, wherein the source of the first PMOS transistor is coupled to a voltage source and the source of the first NMOS transistor is coupled to a ground.

7. The static random access memory cell of claim 6, wherein a second terminal of the first capacitor is coupled to the voltage source or the ground.

8. The static random access memory cell of claim 6, further comprising:
a second switch having a first terminal coupled to the drain of the second PMOS transistor; and
a second capacitor having a first terminal coupled to a second terminal of the second switch.

9. The static random access memory cell of claim 8, wherein a second terminal of the second capacitor is coupled to the voltage source or the ground.

10. The static random access memory cell of claim 8, wherein the second switch is an NMOS transistor or a PMOS transistor.

11. A method for operating a static random access memory cell, the static random access memory cell comprising a first inverter, a second inverter cross coupled with the first inverter, a first capacitor, and a first switch coupled between the first inverter and the first capacitor, the method comprising:
switching off the first switch when data is to be written to the static random access memory cell.

12. The method of claim 11, further comprising switching on the first switch after data is written to the static random access memory cell.

13. The method of claim 11, wherein the static random access memory cell further comprises a second capacitor, and a second switch coupled between the second inverter and the second capacitor, the method further comprising:
switching off the second switch when data is to be written to the static random access memory cell.

14. The method of claim 13, further comprising switching on the second switch after data is written to the static random access memory cell.
